(19) United States
(12) Patent Application Publication
(10) Pub. No.: US 2018/0035568 A1
(43) Pub. Date: Feb. 1, 2018

(54) DATA CENTER COOLING SYSTEM

(71) Applicant: Eliot AHDOOT, Dollard des Ormeaux (CA)

(72) Inventor: Eliot AHDOOT, Dollard des Ormeaux (CA)

(21) Appl. No.: 15/222,682

(22) Filed: Jul. 28, 2016

(51) Int. Cl. H05K 7/20

(52) U.S. Cl. CPC H05K 7/20145; H05K 7/20354

(57) ABSTRACT

There is described a cooling system for a server room. The cooling system has an air handling unit and a direct expansion (DX) unit. The air handling unit has a first duct for inputting cool outside air into the air handling unit and for outputting warmed outside air outside, and a second duct for inputting warm server room air into the air handling unit and for outputting cooled server air into the server room. The air handling unit also includes a heat exchanger for transferring heat from the warm server room air to the cool outside air, and an adiabatic humidifier in the first duct, upstream of the plate heat exchanger, for cooling the cool outside air to increase heat transfer at the plate heat exchanger. The DX unit includes and evaporator which is in thermal communication with the second duct.

### CROSS-REFERENCE TO RELATED APPLICATIONS

This application claims priority from U.S. provisional patent application No. 62/318,839 filed on Apr. 6, 2016.

### BACKGROUND

### (a) Field

The subject matter disclosed generally relates to HVAC systems. More specifically, it relates to data center cooling systems.

### (b) Related Prior Art

Data centers are known for their large energy consumption which is required to cool down the heat-producing equipment found in these facilities.

HVAC systems for data centers differ from those used in “standard” buildings in that they have to work in a cooling mode at all times, 24 hours per day, with strict requirements regarding their downtime.

Improving the efficiency of these HVAC systems is advantageous since the energy savings can become substantial over time, reducing both the cost and the environmental impact of operating data centers.

### SUMMARY

According to an aspect of the invention, there is provided an air handling unit for cooling a server room. The air handling unit comprises a first duct for transporting outside air and a second duct, fluidly distinct from the first duct, for transporting server room air. The air handling unit further comprises a heat exchanger providing thermal communication between the first duct and the second duct, and an adiabatic humidifier in the first duct, upstream of the heat exchanger. The second duct is adapted to receive, downstream of the heat exchanger, a direct expansion (DX) cooling coil for cooling the server room air inside the second duct.

According to an embodiment, the first duct comprises a first duct inlet and a first duct outlet, both located outside the server room.

According to an embodiment, there is further provided a first fan to propel the outside air from the first duct inlet to the first duct outlet.

According to an embodiment, the second duct comprises a first duct inlet and a first duct outlet, both located in the server room.

According to an embodiment, there is further provided a second fan to propel the server room air from the second duct inlet to the second duct outlet.

According to another aspect of the invention, there is provided a cooling system for a server room. The cooling system comprises an air handling unit and a a direct expansion (DX) unit. The air handling unit comprises a first duct for inputting cool outside air into the air handling unit and for outputting warmed outside air outside the server room, and a second duct for inputting warm server room air into the air handling unit and for outputting cooled server room air into the server room. The air handling unit further comprises a heat exchanger for transferring heat from the warm server room air to the cool outside air, and an adiabatic humidifier in the first duct, upstream of the plate heat exchanger, for cooling the cool outside air to increase heat transfer at the plate heat exchanger. The DX unit comprises an evaporator which is in thermal communication with the second duct.

According to an embodiment, the heat exchanger comprises a plate heat exchanger.

According to an embodiment, the DX unit further comprises a condenser located outside server room.

According to an embodiment, the condenser has no thermal communication with the air handling unit.

According to an embodiment, the condenser comprises a standard condenser.

According to an embodiment, the evaporator is for cooling the second duct at a location downstream of the heat exchanger.

According to an embodiment, the adiabatic humidifier comprises nozzles located inside the first duct to disperse droplets of water in the cool outside air to reduce a temperature thereof.

According to another aspect of the invention, there is provided a method for cooling a server room. The method comprises inputting outside air into an air handling unit and inputting server room air into the air handling unit. The outside air is cooled using an adiabatic humidifier. Heat is transferred from the server room air to the outside air using a heat exchanger. The server room air is cooled using a DX cooling coil. The server room air is then outputted to a server room.

According to an embodiment, inputting outside air comprises inputting outside air using a first duct of the air handling unit, and inputting server room air comprises inputting server room air using a second duct of the air handling unit.

According to an embodiment, transferring heat from the server room air to the outside air comprises providing a thermal communication by the heat exchanger between the first duct and the second duct.

According to an embodiment, using a heat exchanger comprises using a plate heat exchanger.

According to an embodiment, inputting outside air comprises propelling the outside air using a first fan that is located upstream of the adiabatic humidifier.

According to an embodiment, inputting server room air comprises propelling the server room air using a second fan that is located downstream of the heat exchanger.

According to an embodiment, wherein cooling the server room air using a DX cooling coil comprises using a DX condenser to evacuate, away from the air handling unit, heat extracted by the DX cooling coil.

As will be realized, the subject matter disclosed and claimed is capable of modifications in various respects, all without departing from the scope of the claims. Accordingly, the drawings and the description are to be regarded as illustrative in nature, and not as restrictive and the full scope of the subject matter is set forth in the claims.

### BRIEF DESCRIPTION OF THE DRAWINGS

Further features and advantages of the present disclosure will become apparent from the following detailed description, taken in combination with the appended drawings, in which:

FIG. 1 is a diagram illustrating a cooling system, according to an embodiment; and

FIG. 2 is a flowchart illustrating a method for cooling a server room, according to an embodiment.

It will be noted that throughout the appended drawings, like features are identified by like reference numerals.

### DETAILED DESCRIPTION

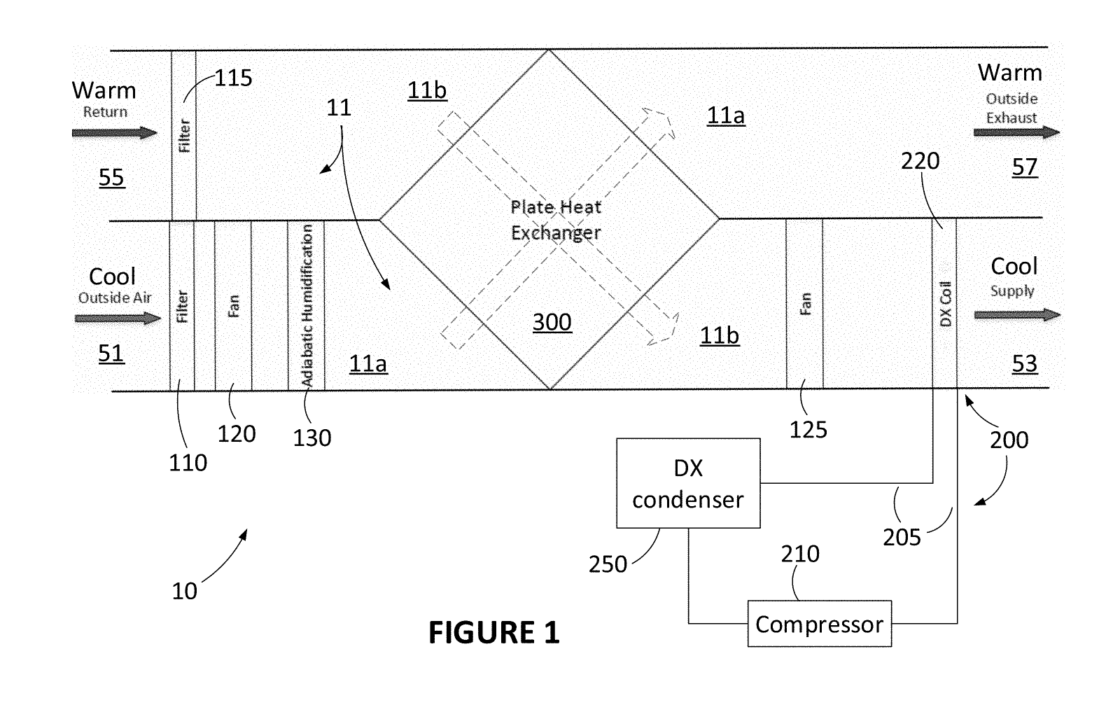

In FIG. 1, there is disclosed an embodiment of a cooling system 10 for cooling a room such as a data center. The cooling system 10 comprises two cooling mechanisms: fresh air from the outside (outside or external the server room) to cool down the air from the server room using a plate heat exchanger system, and a DX unit to cool down the air using a cooling coil right before supply to the server room. As described further below, an adiabatic humidifier is added to the system.

Fresh air, also referred to as outside air, is taken from the outside (e.g., outdoor/open air) and brought into the system by an input in fluid communication with the outside. The outside air has a temperature, humidity and content in particles that cannot be controlled. However, given the high amounts of heat produced by the servers and other electric equipment in the data center, the temperature of the air coming from the server rooms is (almost) always higher than the temperature of the outside air, at least in the temperate climates for which the use of the system is contemplated.

Since the outside air is expected to be of a temperature lower than the air extracted from the server room, the outside air can be considered as a source for cooling the air of server room, i.e., the temperature difference between the cooler outside air and the warmer server air is used to generate a heat flow from the warmer server air toward the cooler outside air, thereby cooling the warmer server air which can later be reinjected into the server room with a lower temperature.

Heat transfer between these air masses with different temperatures can advantageously be performed using a heat exchanger 300. More precisely, the use of a plate heat exchanger 300 is preferable over other types of heat exchangers because it allows for a reduction in energy consumption which, over time, results in substantial energy savings. For example, compared to a sensible wheel heat exchanger, the plate heat exchanger 300 does not require energy to spin the wheel. Since the plate heat exchanger 300 works constantly (i.e., without stopping), the energy savings are significant, and this type of heat exchanger should be preferred over other types which consume more energy.

Another way to cool down the warm server air is to use a direct-expansion (DX) unit 200. The DX unit 200 is an air conditioning system that uses a refrigerant vapor expansion/compression cycle to directly cool supply air. The evaporator is in direct contact with the supply air (i.e., there is no intermediate fluid for heat transfer). DX units can be made as packaged systems (all elements packaged together) or split systems (evaporator and fan are inside the building; remaining parts are elsewhere, usually outside). Advantageously, the DX unit comprises a standard condenser, such as a condenser of a standard split system that can be located outside. Being able to use such a DX condenser is advantageous in that in allows for a substantial reduction in cost of engineering/design, construction and maintenance of the cooling system, compared to custom DX units with non-standard condensers. Cooling a data center often involves using custom DX units that are specifically designed for the needs of a data center.

Using a DX unit 200 in combination with a plate heat exchanger 300 is advantageous in that the cooling load required for the DX unit is lower than when it is used alone; a standard DX unit can therefore be used.

The cooling system 10 can thus be described as comprising an air handling unit 11, which comprises ducts to transport air and other equipment acting on the air flowing therein, and a DX unit 200 which contains a refrigerant therein and that acts on a specific portion of the air handling unit 11. The air handling unit 11 is divided in two distinct ducts or paths, namely the outside air section or first duct 11a in which outside air flows, and the server room section or second duct 11b, in which the server air flows. There is preferably no fluid communication between the sections or ducts 11a, 11b to avoid contaminating the server room. The ducts 11a, 11b can thus be considered as fluidly distinct, since they do not communicate; i.e., the fluids being transported therein are fluidly distinct. However, there is a thermal communication between both sections; this thermal communication (i.e., heat transfer only, wherein both air masses stay inside their respective duct 11a or 11b) takes place at the plate heat exchanger 300.

According to an embodiment, and as shown in FIG. 1, a filter 110 is provided at the point of entry 51 of the outside air into the outside air section or first duct 11a of the air handling unit 11. The filter 110 allows for filtering the outside air to remove particles, powders and other small debris that can be in suspension in the air from outside.

In order to create fluid movement inside the air handling unit 11, and in the appropriate direction, a first fan 120 is provided close to the point of entry 51 (first duct inlet) of the outside air in the first duct 11a, as shown in FIG. 1. This figure shows that the first fan 120 is located just downstream of the filter 110. If the filter is located upstream of the first fan 120, particles and other undesirable contents in the outside is removed before the passage into the first fan 120, which is preferable to avoid the wear of the equipment that would be upstream of the filter 110.

A humidifier 130 is provided in the system, more particularly in the outside air section or first duct 11a of the air handling unit 11. As shown in FIG. 1, it can be located just downstream of the fan 120. Advantageously, the humidifier 130 is an adiabatic humidifier, which has a low energy consumption compared to other types of humidifiers such as isothermal humidifiers. Moreover, adiabatic humidifiers are simple to operate and to maintain.

The filter 110 is advantageously located upstream of the adiabatic humidifier 130 in the outside air section 11a of the air handling unit 11, which implies that impurities that could be found in the outside air are removed before the outside air reaches the adiabatic humidifier 130. This is to avoid buildup of undesirable microbial activity that could result from the mixing of impurities with moisture. Since impurities are removed, this mixing does not occur.

The adiabatic humidifier 130 is used to lower the temperature of the outside air brought into the air handling unit 11. Indeed, when water droplets are introduced into the air, evaporative cooling occurs. The water droplets vaporize, at least partially, in an adiabatic process, i.e., without external heat exchange. This process is also isenthalpic, which means that when the water droplets vaporize and increase the vapor partial pressure in the air, the temperature of the dry air decreases. This is because the vaporizing water extracts thermal energy from the dry air while vaporizing without external heat supply. The result is a mass of air that is more humid (increased moisture/water vapor partial pressure) and colder, while keeping the same enthalpy.

In other words, the adiabatic humidifier 130 provides water that can vaporize, thereby reducing the cooling loads on other pieces of equipment. This reduced cooling load requirement also explains why standard DX units are sufficient for the cooling system.

The use of an adiabatic humidifier 130 can be practiced using various technologies, although some of the existing technologies may be inappropriate in this case (ultrasonic humidifiers, which have long off-line times; centrifugal humidifiers, which need open spaces). A wetted media humidifier is an example of an adiabatic humidifier. Preferably, the adiabatic humidifier 130 is a pressurized water humidifier. The pressurized water humidifier comprises a pump for propulsion and water dispersion nozzles that disperse droplets of water into the air. A pressurized water humidifier uses treated water and provides high-quality humidification and cooling. Air can be mixed to the water to produce droplets.

Since the outside air is the coolest downstream of the adiabatic humidifier 130, the thermal contact at the plate heat exchanger 300 can occur at this point. The ducts of the outside air section 11a (first duct) and of the server room section 11b (second duct) are put in thermal contact using the plate heat exchanger 300. In the server room section 11b, the warm server room air that just returns from the server room into the air handling unit 11 is immediately cooled down by the plate heat exchanger 300.

As mentioned above, a DX unit 200 is provided. The DX unit 200, which can advantageously be provided as a standard DX unit, comprises a DX cooling coil 220 that cools down the fluid (i.e., server room air) in the second duct 11b, which is where the DX cooling coil 220 is located (i.e., the server room section 11b which contains the cooled server room air, right before the supply 53). In the DX cooling coil 220, the refrigerant should be in a liquid state; should be in thermal communication with the air in the server room side of the air handling unit 11. Since the DX cooling coil 220 is in thermal communication with the air to be supplied into the server room, it should be able to absorb thermal energy from the air. The result is an increase of the liquid refrigerant temperature, evaporation (i.e. vaporization) thereof, and decrease of the air temperature (the air to be supplied into the server room). The DX cooling coil 220 can also be referred to as an evaporator because of the physical process that occurs therein. Therefore, the refrigerant in the DX cooling coil 220, when its temperature decreases and when its physical state changes, is able to cool down the air to be supplied into the server room.

In addition to the DX cooling coil 220, the DX unit 200 comprises a compressor 210 to increase the pressure of the refrigerant which flows within the DX unit piping 205. The compressor 210 should be located just downstream of the DX cooling coil 220. At the location of the compressor 210, the refrigerant is gaseous, which means that passing through the compressor 210 substantially increase its pressure.

The DX unit 200 further comprises a condenser 250. Preferably, the condenser 250 is a standard condenser, e.g., it is a unit located on the rooftop of the building hosting the server rooms. The advantages of a standard condenser 250 have been discussed above. The condenser 250 is at the location on the path of the refrigeration where it is in thermal communication with the outside. Since the refrigerant is now a gas that has been warmed in the DX cooling coil 220, the gas is warmer than the outside air and can release its heat into the outside air, outside of the cooling system 10. The heat is not reinjected into the air handling unit 11; the heat previously extracted from the second duct 11b by the DX cooling coil 220 is rather evacuated away from the air handling unit 11. This heat evacuation away from the air handling unit 11 contributes to the efficiency of the cooling system 10. During this process, the gaseous refrigerant cools down and eventually condenses into a liquid refrigerant that can be sent back to the DX cooling coil 220 through the DX unit piping 205.

An additional fan or second fan 125 is provided in the second duct 11b closer to the point of supply 53 (second duct outlet) of the air into the server room in order to propel the cooled server room air into the room, for example, through a diffuser (not shown) located at the point of supply 53 in the server room. A point of return 55 (second duct inlet) in the server room is used to capture the warm server air from the server room; a filter 115 is provided to remove undesirable particles, dust, etc., originating from the server room.

From this point, the return air from the server room, which is warm, can be put in contact with the plate heat exchanger 300 to be cooled down. Thereafter, this air can be cooled by the DX cooling coil 220 and then outputted from the air handling unit 11 to the server room again.

The warmed outside air in the first duct 11a that is warmed up at the plate heat exchanger 300 is propelled toward the exhaust or point of exit 57 (first duct outlet) of the air handling unit 11 to be outputted from the outside air section or first duct 11a of the air handling unit 11.

The overall result is a cooling system 10 that can cool down the server room(s) of the data center with a high efficiency, i.e., using a relatively small amount of energy given the result.

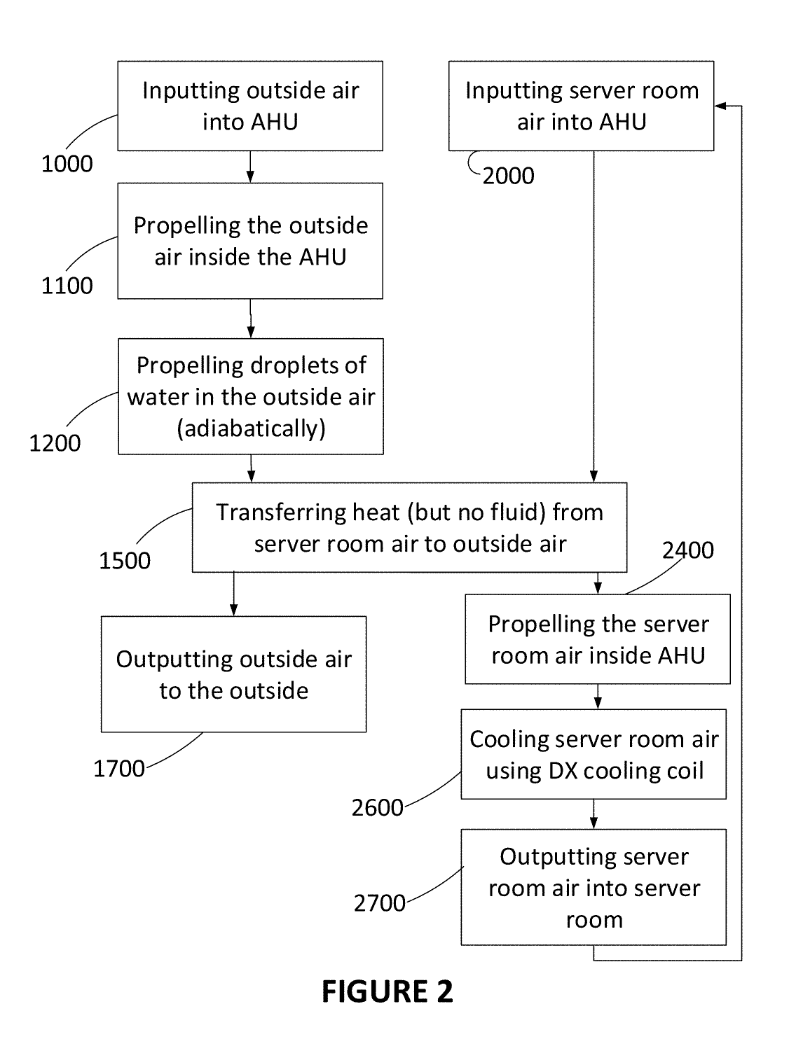

FIG. 2 illustrates the overall process of cooling a server room using a system such as the cooling system 10. Flows of outside air and server room are shown to be fluidly distinct. All actions but the heat transfer affects only one of the air flows. For the outside air: the outside air is first inputted into the air handling unit (step 1000), with the help of a first fan that propels the outside air (step 1100). Droplets of water are pulverized or propelled in the outside air (step 1200). The system should be designed to prevent heat transfer to occur at this step between the outside air and outside the ducting so that the process is adiabatic. The outside air is then subject to a heat transfer from the server room air (step 1500) and its temperature increases. It is then outputted to the outside (step 1700). For the server room air: the server room air is first inputted into the air handling unit (step 2000). It is subject to a heat transfer (step 1500), where its heat is transferred to the outside air (which was previously cooled down using droplets of water), so that the temperature of the server room air decreases. Propelling power may be provided thereafter (step 2400) to ensure proper flow of server room air inside the air handling unit. The server room air is then further cooled down by a DX cooling coil (step 2600). It is then outputted into the server room air (step 2700).

While preferred embodiments have been described above and illustrated in the accompanying drawings, it will be evident to those skilled in the art that modifications may be made without departing from this disclosure. Such modifications are considered as possible variants comprised in the scope of the disclosure.

1. A cooling system for a server room in a building, the cooling system comprising:
an air handling unit comprising:
a first duct for inputting cool outside air into the air handling unit and for outputting warmed outside air outside the server room;
a second duct, fluidly distinct from the first duct, for inputting warm server room air into the air handling unit and for outputting cooled server room air into the server room;
a heat exchanger for transferring heat from the warm server room air to the cool outside air;
an adiabatic humidifier in the first duct, upstream of the heat exchanger, for cooling the cool outside air to increase heat transfer at the heat exchanger;
a direct expansion unit comprising:
an evaporator which is in thermal communication with the second duct for cooling server room air inside the second duct;
a condenser distant from the air handling unit and outside the building for evacuating into the cool outside air.

2. The cooling system of claim 1, wherein the heat exchanger comprises a plate heat exchanger.

3-4. (canceled)

5. The cooling system of claim 1, wherein the condenser comprises a rooftop condenser.

6. The cooling system of claim 2, wherein the evaporator is for cooling the server room air inside the second duct at a location downstream of the heat exchanger.

7. The cooling system of claim 2, wherein the adiabatic humidifier comprises nozzles located inside the first duct to disperse droplets of water in the cool outside air to reduce a temperature of the cool outside air.

8. A method for cooling a server room, the method comprising:
inputting outside air from an outside atmosphere into an air handling unit;
inputting server room air into the air handling unit;
propelling droplets of water in the outside air while preventing heat transfer with outside the air handling unit, thereby cooling the outside air;
transferring heat from the server room air to the outside air using a heat exchanger;
cooling the server room air using a direct expansion cooling coil;
evacuating away from the air handling unit, into the outside atmosphere, heat extracted by the direct expansion cooling coil using a direct expansion condenser distant from the air handling unit and located in the outside atmosphere; and
outputting the server room air to a server room.

9. The method of claim 8, wherein inputting outside air and inputting server room air comprise inputting outside air and server room while keeping them fluidly distinct.

10. The method of claim 9, wherein transferring heat from the server room air to the outside air comprises providing a thermal communication by the heat exchanger while keeping the server room air and the outside air fluidly distinct.

11. The method of claim 10, wherein using a heat exchanger comprises using a plate heat exchanger.

12. The method of claim 9, wherein inputting outside air comprises propelling the outside air prior to propelling droplets of water in the outside air.

13. The method of claim 12, wherein inputting server room air comprises propelling the server room air using a fan that is located downstream of the heat exchanger.

14. (canceled)

15. The method of claim 11, further comprising providing a direct path from the plate heat exchanger to a system exhaust so that the outside air gone through the plate heat exchanger is not in thermal communication with any device in the air handling unit before reaching the exhaust and the outside atmosphere.

16. The method of claim 11, further comprising providing a filter in a path from the point of return from the server room to the plate heat exchanger so that the server room air to go through the plate heat exchanger is free of dust.

17. The cooling system of claim 2, wherein the first duct forms a direct path, free of any device, from the plate heat exchanger to a system exhaust so that the warmed outside air gone through the plate heat exchanger is not in thermal communication with any device in the air handling unit before reaching the exhaust and the outside atmosphere.

18. The cooling system of claim 2, wherein the second duct forms a path from the point of return from the server room to the plate heat exchanger so that the warm server room air to go through the plate heat exchanger is free of dust.
